(19) United States
(12) Patent Application Publication
(10) Pub. No.: US 2026/0206457 A1
(43) Pub. Date: Jul. 16, 2026

(54) DISPLAY DEVICE AND ELECTRONIC DEVICE INCLUDING DISPLAY DEVICE

(71) Applicant: Samsung Display Co., Ltd., Yongin-si (KR)

(72) Inventors: Seung Sue RYU, Yongin-si (KR); Ki Kyung YOUK, Yongin-si (KR); Jae Hak LEE, Yongin-si (KR); Dae Hyuk IM, Yongin-si (KR); Sung Woon IM, Yongin-si (KR)

(21) Appl. No.: 19/353,999

(22) Filed: Oct. 9, 2025

(30) Foreign Application Priority Data
Jan. 13, 2025 (KR) 10-2025-0004710

(51) Int. Cl. H10K 59/80; H10K 59/121; H10K 59/131; H10K 102/00; H10K 102/10

(52) U.S. Cl. CPC H10K 59/80517; H10K 59/1213; H10K 59/131; H10K 2102/103; H10K 2102/351

(57) ABSTRACT

A display device and an electronic device including the display device are disclosed. The display device may include a display area and a non-display area in a periphery of the display area; a base layer over the display area and the non-display area; a pad portion on the base layer in the non-display area; and a light-emitting element on the base layer in the display area. The pad portion may include: conductive layers electrically connected to each other, an intermediate cushion layer between the conductive layers, and an upper connection layer electrically connected to the conductive layers and provided on top of the pad portion. The light-emitting element may include: a first electrode, a second electrode, and a light-emitting layer electrically connected between the first electrode and the second electrode. The upper connection layer and the first electrode may include a same or substantially the same conductive material.

### CROSS-REFERENCE TO RELATED APPLICATION

The present application claims priority to and the benefit of Korean Patent Application No. 10-2025-0004710, filed on January 13, 2025, in the Korean Intellectual Property Office, the entire disclosure of which is incorporated herein by reference.

### BACKGROUND

### 1. Field

One or more embodiments of the present disclosure relate to a display device and an electronic device including the display device.

### 2. Description of the Related Art

As interest in information display has increased, research and development on display devices are continuously being conducted.

Pixels of the display devices may emit light based on an electrical signal provided through the pad and the driver. For example, a pad formed or provided on a substrate and/or the like of a display device may receive an electrical signal by being electrically connected to another component, such as a driving unit.

The electrical connection between the pad and the driving unit is desired to be reliably or suitably formed or provided, and the possibility of electrical defects, such as short or open coupling around the pad, is desired to be effectively or suitably reduced.

### SUMMARY

One or more aspects of embodiments of the present disclosure are directed toward a display device and an electronic device including the display device, in which a risk of short or open defects occurring in a pad and a periphery of the pad may be reduced.

One or more aspects of embodiments of the present disclosure are directed toward a display device and an electronic device including the display device, in which an electrical connection path may be closely formed or provided and reliability of an electrical signal may be improved or enhanced.

Additional aspects of embodiments will be set forth in part in the description which follows and, in part, will be apparent from the description or may be learned by practice of the presented embodiments of the disclosure.

According to one or more embodiments of the present disclosure, a display device may include a display area and a non-display area formed or provided in a periphery of the display area. The display device may include: a base layer formed or provided over the display area and the non-display area; a pad portion disposed or provided on the base layer in the non-display area; and a light-emitting element disposed or provided on the base layer in the display area. The pad portion may include: conductive layers (e.g., electrically conductive layers) electrically connected to each other, an intermediate cushion layer disposed or provided between the conductive layers, and an upper connection layer electrically connected to the conductive layers and formed or provided on top of the pad portion. The light-emitting element may include: a first electrode, a second electrode, and a light-emitting layer electrically connected between the first electrode and the second electrode. The upper connection layer and the first electrode may include a same or substantially the same conductive material (e.g., electrically conductive material).

According to one or more embodiments, the upper connection layer may include a first upper connection layer, a second upper connection layer on the first upper connection layer, and a third upper connection layer on the second upper connection layer. The first electrode may include a (1-1)th electrode, a (1-2)th electrode on the (1-1)th electrode, and a (1-3)th electrode on the (1-2)th electrode. The first upper connection layer and the (1-1)th electrode may include a same or substantially the same transparent (e.g., substantially transparent) conductive (e.g., electrically conductive) material. The second upper connection layer and the (1-2)th electrode may include a same or substantially the same reflective (e.g., substantially reflective) conductive (e.g., electrically conductive) material. The third upper connection layer and the (1-3)th electrode may include a same or substantially the same transparent (e.g., substantially transparent) conductive (e.g., electrically conductive) material.

According to one or more embodiments, the first upper connection layer and the third upper connection layer may include indium tin oxide (ITO). The second upper connection layer may include one or more selected from among gold (Au), silver (Ag), aluminum (Al), copper (Cu), and nickel (Ni).

According to one or more embodiments, the (1-3)th electrode may have a first thickness. The third upper connection layer may have a second thickness that is less than the first thickness.

According to one or more embodiments, the first upper connection layer may have a thickness of 10 Å to 300 Å. The second upper connection layer may have a thickness of 500 Å to 10000 Å. The third upper connection layer may have a thickness of 10 Å to 300 Å.

According to one or more embodiments, the display device may further include: a gate conductive (e.g., electrically conductive) layer disposed or provided on the base layer in the display area; an active (e.g., electrically active) layer disposed or provided on the base layer in the display area; a first transistor electrode and a second transistor electrode that are electrically connected to the active layer; and a via layer covering the first transistor electrode and the second transistor electrode. The conductive layers may include a first conductive (e.g., electrically conductive) layer on the base layer, a second conductive (e.g., electrically conductive) layer on the first conductive layer, and a third conductive (e.g., electrically conductive) layer covering the intermediate cushion layer and electrically connected to the second conductive layer. The first conductive layer may include a same or substantially the same conductive (e.g., electrically conductive) material as the gate conductive layer. The second conductive layer may include a same or substantially the same conductive (e.g., electrically conductive) material as the first transistor electrode and the second transistor electrode. The intermediate cushion layer may include a same or substantially the same organic material as the via layer.

According to one or more embodiments, the upper connection layer may entirely (e.g., substantially entirely) cover an upper surface of the third conductive layer and may cover at least a portion of a side end portion of the third conductive layer.

According to one or more embodiments, the upper connection layer may include a first upper connection layer, a second upper connection layer on the first upper connection layer, and a third upper connection layer on the second upper connection layer. The first electrode may include a (1-1)th electrode, a (1-2)th electrode on the (1-1)th electrode, and a (1-3)th electrode on the (1-2)th electrode. The first upper connection layer and the (1-1)th electrode may include a same or substantially the same reflective (e.g., substantially reflective) conductive (e.g., electrically conductive) material. The second upper connection layer and the (1-2)th electrode may include a same or substantially the same reflective (e.g., substantially reflective) conductive (e.g., electrically conductive) material. The third upper connection layer and the (1-3)th electrode may include a same or substantially the same reflective (e.g., substantially reflective) conductive (e.g., electrically conductive) material.

According to one or more embodiments, the display device may further include: a connection portion including a drive integrated circuit (a drive IC) and a connection member patterned on the drive IC; and a drive circuit portion electrically connected to the connection portion. The pad portion may be electrically connected to the connection member through the upper connection layer.

According to one or more embodiments, the connection member may include a conductive (e.g., electrically conductive) bump or a lead structure. The conductive layers may include a first conductive (e.g., electrically conductive) layer on the base layer, a second conductive (e.g., electrically conductive) layer on the first conductive layer, and a third conductive (e.g., electrically conductive) layer covering the intermediate cushion layer and electrically connected to the second conductive layer. The upper connection layer may be disposed or provided on the third conductive layer. The connection member and the third conductive layer may be spaced and/or apart (e.g., spaced apart or separated) from each other.

According to one or more embodiments, the third upper connection layer may include an opening exposing a portion of the second upper connection layer. The connection member may be in contact with the second upper connection layer through the opening.

According to one or more embodiments, the third conductive layer may include a (3-1)th conductive (e.g., electrically conductive) layer, a (3-2)th conductive (e.g., electrically conductive) layer on the (3-1)th conductive layer, and a (3-3)th conductive (e.g., electrically conductive) layer on the (3-2)th conductive layer. The (3-1)th conductive layer and the (3-3)th conductive layer may include titanium (Ti). The (3-2)th conductive layer may include aluminum (Al). A top surface of the (3-2)th conductive layer may not be exposed by the (3-3)th conductive layer.

According to one or more embodiments, the intermediate cushion layer may include an organic material having a smaller modulus than the conductive layers. The intermediate cushion layer may have a cross-sectional shape having a curvature.

According to one or more embodiments of the present disclosure, a display device may include a display area and a non-display area formed or provided in a periphery of the display area. The display device may include: a base layer formed or provided over the display area and the non-display area; a pad portion disposed or provided on the base layer in the non-display area; and a light-emitting element disposed or provided on the base layer in the display area. The pad portion may include: conductive layers (e.g., electrically conductive layers) electrically connected to each other, an intermediate cushion layer disposed or provided between the conductive layers, and a lower cushion layer disposed or provided between the base layer and the intermediate cushion layer. At least one selected from among the conductive layers may be disposed or provided between the intermediate cushion layer and the lower cushion layer.

According to one or more embodiments, the display device may further include: a gate conductive (e.g., electrically conductive) layer disposed or provided on the base layer in the display area; an active (e.g., electrically active) layer disposed or provided on the base layer in the display area; a first transistor electrode and a second transistor electrode that are electrically connected to the active layer; a first via layer covering the gate conductive layer; and a second via layer disposed or provided on the first via layer and covering the first transistor electrode and the second transistor electrode. The conductive layers may include a first conductive (e.g., electrically conductive) layer on the base layer, a second conductive (e.g., electrically conductive) layer on the first conductive layer, and a third conductive (e.g., electrically conductive) layer covering the intermediate cushion layer and electrically connected to the second conductive layer. The first conductive layer may include a same or substantially the same conductive (e.g., electrically conductive) material as the gate conductive layer. The second conductive layer may include a same or substantially the same conductive (e.g., electrically conductive) material as the first transistor electrode and the second transistor electrode. The lower cushion layer may include a same or substantially the same organic material as the first via layer. The intermediate cushion layer may include a same or substantially the same organic material as the second via layer.

According to one or more embodiments, the conductive layers and the intermediate cushion layer may be disposed or provided in a region where the lower cushion layer is disposed or provided.

According to one or more embodiments, the display device may further include: a gate insulating (e.g., electrically insulating) layer, at least a portion of the gate insulating layer being disposed or provided between the gate conductive layer and the active layer; and an additional lower cushion layer including a same or substantially the same material as the gate insulating layer and disposed or provided between the first conductive layer and the base layer.

According to one or more embodiments, the first conductive layer, the second conductive layer, the third conductive layer, and the intermediate cushion layer may be disposed or provided in a region where the additional lower cushion layer is disposed or provided.

According to one or more embodiments of the present disclosure, an electronic device may include: a processor configured or provided to provide input control signal; a display device configured or provided to output image information; and a power module configured or provided to supply power to the display device. The display device may include: a display area and a non-display area formed or provided in a periphery of the display area; a base layer formed or provided over the display area and the non-display area; a pad portion disposed or provided on the base layer in the non-display area; and a light-emitting element disposed or provided on the base layer in the display area. The pad portion may include: conductive layers (e.g., electrically conductive layers) electrically connected to each other, an intermediate cushion layer disposed or provided between the conductive layers, and an upper connection layer electrically connected to the conductive layers and formed or provided on top of the pad portion. The light-emitting element may include: a first electrode, a second electrode, and a light-emitting layer electrically connected between the first electrode and the second electrode. The upper connection layer and the first electrode may include a same or substantially the same conductive material (e.g., electrically conductive material).

According to one or more embodiments, the electronic device may be applied to a smartphone, a tablet PC, a laptop, a TV, a monitor for a desk, smart glasses, a head mounted display, a smart watch, a center information display (CID) disposed or provided on an instrument panel, a center fascia, and/or a dashboard of a vehicle, and/or a room mirror display.

According to one or more embodiments of the present disclosure, a display device and an electronic device including the display device may be provided, in which a risk of short or open defects occurring in a pad and a periphery of the pad may be reduced.

According to one or more embodiments of the present disclosure, a display device and an electronic device including the display device may be provided, in which an electrical connection path is closely formed or provided and reliability of an electrical signal may be improved or enhanced.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a schematic plan view illustrating a display device according to one or more embodiments.

FIG. 2 is a schematic cross-sectional view illustrating a display device according to one or more embodiments.

FIG. 3 is a schematic cross-sectional view illustrating a pad portion according to one or more embodiments.

FIG. 4 is a schematic cross-sectional view illustrating a display device including a pad according to one or more embodiments.

FIG. 5 is a schematic diagram illustrating an electrical connection structure between a pad portion and a connection portion according to one or more embodiments.

FIG. 6 is a schematic cross-sectional view illustrating a pad portion according to one or more embodiments.

FIGS. 7 and 9-11 are schematic cross-sectional views illustrating a display device including a pad portion according to one or more embodiments.

FIG. 8 is a schematic diagram illustrating an electrical connection structure between a pad portion and a connection portion according to one or more embodiments.

FIG. 12 is a block diagram of an electronic device according to one or more embodiments.

FIG. 13 is a schematic diagram of an electronic device according to one or more embodiments.

### DETAILED DESCRIPTION

In order to fully understand the aspects and features of the present disclosure, the subject matter of the present disclosure will be described below in more detail with reference to the accompanying drawings. The subject matter of the present disclosure may, however, be embodied in one or more forms and should not be construed as being limited to one or more embodiments set forth herein, and one or more changes and modifications can be made. Rather, these embodiments are provided as examples so that this disclosure will be thorough and complete and will fully convey the aspects and features of the present disclosure to those skilled in the art to which the present disclosure pertains.

The utilization of “may” if (e.g., when) describing embodiments of the present disclosure refers to “one or more embodiments of the present disclosure.”

In the context of the present disclosure and unless otherwise defined, the terms, "use," "using," and "used," may be considered synonymous with the terms, "utilize," "utilizing," and "utilized," respectively.

As used herein, the term, "and/or," includes any and all combinations of one or more of the associated listed items. For example, "A and/or B" indicates cases where it is A, B, or both (e.g., simultaneously) A and B.

Throughout the present disclosure, the expression "at least one of a, b, or c" indicates only a, only b, only c, both (e.g., simultaneously) a and b, both (e.g., simultaneously) a and c, both (e.g., simultaneously) b and c, all of a, b, and c, or variations thereof.

As used herein, the terms, "substantially," "about," and/or the like, are used as terms of approximation and not as terms of degree and are intended to account for the inherent deviations in measured or calculated values that would be recognized by those of ordinary skill in the art.

Any numerical range recited herein is intended to include all sub-ranges of the same numerical precision subsumed within the recited range. For example, a range of "1.0 to 10.0" is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in the present disclosure is intended to include all higher numerical limitations subsumed therein. Accordingly, Applicant reserves the right to amend this specification, including the claims, to expressly recite any sub-range subsumed within the ranges expressly recited herein.

The terms, “first,” “second,” and/or the like, may be used to describe one or more suitable components, but the components should not be limited by the terms. The terms may be used for the purpose of distinguishing one component from another. For example, a first component may be referred to as being a second component, and similarly, a second component may also be referred to as being a first component, without departing from the scope of the present disclosure.

The singular forms, “a,” “an,” and “the,” include plural references unless the context clearly requires otherwise.

In the present disclosure, the terms, “include,” “including,” “have,” “having,” and/or the like are intended to designate the presence of a feature, a number, a step, an operation, a component, a part, or a combination thereof as described in the specification and should not be understood to preclude the presence or possibility of addition of one or more other features, numbers, steps, operations, components, parts, or combinations thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

If (e.g., when) a portion of a layer, a film, a region, a plate, and/or the like is “on” another portion, this includes not only the case where it is “directly on” the other portion, but also the case where there is another portion in the middle. In contrast, if (e.g., when) a portion is referred to as being “directly on” another portion, there are no intervening portions present therebetween.

In the present disclosure, if (e.g., when) a portion of a layer, a film, a region, a plate, and/or the like is formed or provided on another portion, the formed or provided direction is not limited to an upper direction but includes a side or a lower direction. In contrast, if (e.g., when) a portion of a layer, a film, an area, a plate, and/or the like is "below" another portion, this includes not only the case where the other portion is "right below" or “directly below” but also the case where there is another portion in the middle.

In the drawings, the thickness, ratio, and dimension of components may be exaggerated for effective description of the technical content.

In the context of the present disclosure and unless otherwise defined, plan view is an orthographic projection of a three-dimensional object from the position of a horizontal plane that intersects the object. For example, it is a top-down view, illustrating the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

One or more embodiments of the present disclosure relate to a display device and an electronic device including the display device. Hereinafter, a display device and an electronic device including the display device according to one or more embodiments will be described with reference to the accompanying drawings.

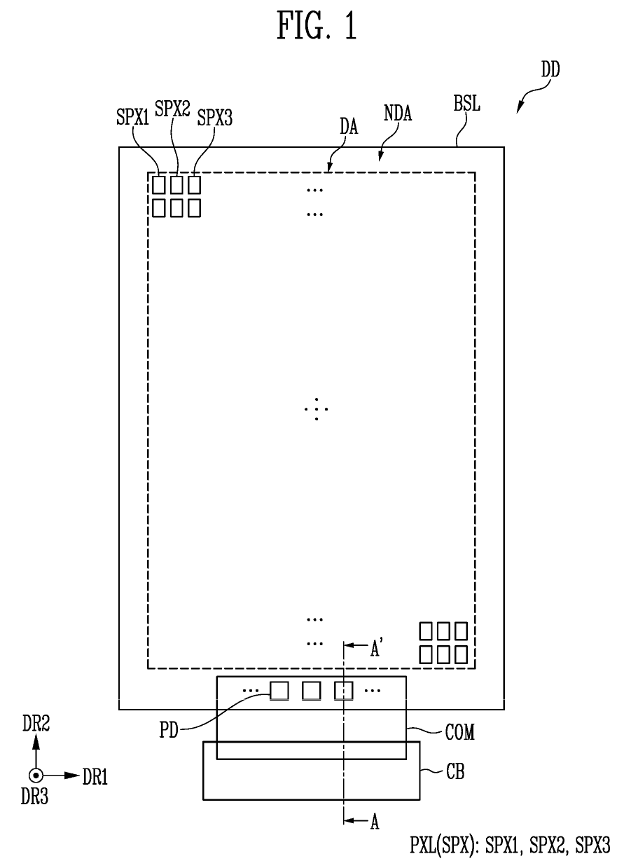

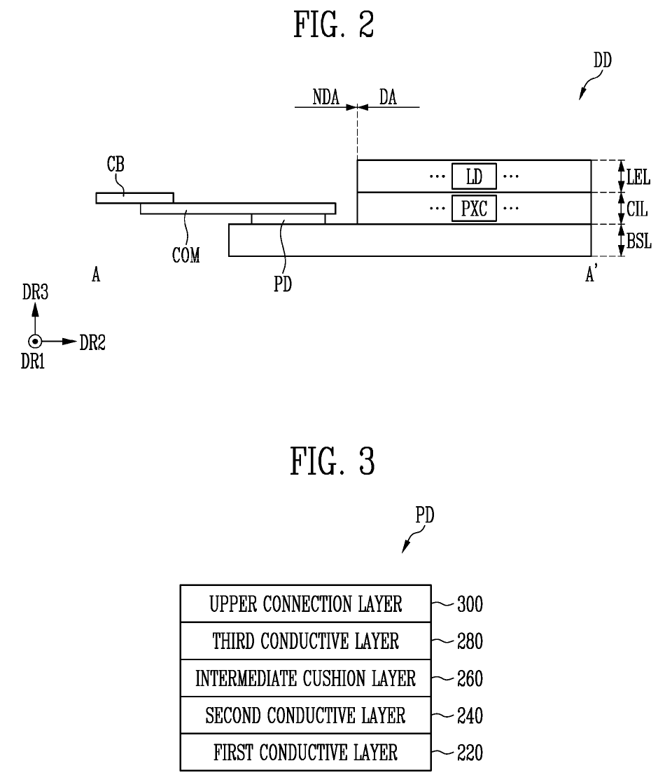

FIG. 1 is a schematic plan view illustrating a display device according to one or more embodiments. FIG. 2 is a schematic cross-sectional view illustrating a display device according to one or more embodiments. FIG. 2 is also a schematic cut-away sectional view according to the line A to A' of FIG. 1.

Referring to FIGS. 1 and 2, the display device DD may include a base layer BSL and a pixel PXL disposed or provided on the base layer BSL. The display device DD may further include a pad portion PD, a connection portion COM, and a drive circuit portion CB.

The display device DD (or the base layer BSL) may include a display area DA and a non-display area NDA. The non-display area NDA may refer to an area outside of the display area DA. The non-display area NDA may be around (e.g., surround) at least portion of the display area DA. The non-display area NDA may be formed or provided in a periphery of the display area DA.

The base layer BSL may form or provide a base surface of the display device DD. According to one or more embodiments, the base layer BSL may be a lower substrate to dispose or provide layers that form or provide the display device DD. The base layer BSL may be a rigid substrate, a flexible substrate, and/or a film. For example, the base layer BSL may include a glass material. In one or more embodiments, the base layer BSL may include a silicon material. In one or more embodiments, the base layer BSL may include polyimide. However, embodiments of the present disclosure are not limited thereto.

The plane defined herein may be defined with reference to a plane on which the base layer BSL is disposed or provided, as a direction extending in the first direction DR1 and the second direction DR2. According to one or more embodiments, the third direction DR3 may be a thickness direction of the base layer BSL, and the third direction DR3 may also be a light emission direction of the display device DD.

The display area DA may refer to an area in which pixels PXL are disposed or provided. The non-display area NDA may refer to an area where the pixel PXL is not disposed or provided. A drive circuit portion, wirings, and pads connected to the pixel PXL of the display area DA may be disposed or provided in the non-display area NDA.

According to one or more embodiments, the pixel PXL (or the sub-pixels SPX) may be arranged or provided according to a stripe arrangement structure, a PENTILE^{®} arrangement structure (e.g., an RGBG matrix, an RGBG structure, or an RGBG matrix structure) and/or the like. PENTILE^{®} is a duly registered trademark of Samsung Display Co., Ltd. However, embodiments of the present disclosure are not limited thereto, and one or more embodiments may be applied to the present disclosure.

According to one or more embodiments, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one sub-pixel selected from among the first sub-pixel SPX1, the second sub-pixel SPX2, and the third sub-pixel SPX3 may form or provide a pixel unit configured or provided to emit light of one or more suitable colors.

Each of the first sub-pixel SPX1, the second sub-pixel SPX2, and the third sub-pixel SPX3 may emit light of one color.

For example, the first sub-pixel SPX1 may be a red pixel that emits red (e.g., a first color) light. The second sub-pixel SPX2 may be a green pixel that emits green (e.g., a second color) light. The third sub-pixel SPX3 may be a blue pixel that emits blue light (e.g., a third color). The red pixel may provide light in a wavelength band of about 600 nm to about 750 nm. The green pixel may provide light in a wavelength band of about 480 nm to about 560 nm. The blue pixel may provide light in a wavelength band of about 370 nm to about 460 nm.

According to one or more embodiments, the number of the second sub-pixels SPX2 may be greater than the number of the first sub-pixel SPX1 and the number of the third sub-pixels SPX3. However, the color, type (or kind), and/or number of the first sub-pixel SPX1, the second sub-pixel SXX2, and the third sub-pixel SX3 that form or provide each pixel unit are not limited to the disclosed embodiments.

The pad portion PD may be disposed or provided in the non-display area NDA. The pad portion PD may be disposed or provided on the base layer BSL. For example, the pad portion PD may be provided on the base layer BSL around an edge periphery of the base layer BSL.

The pad portion PD may interface the configurations or arrangement formed or provided on the drive circuit portion CB and the base layer BSL.

The pad portion PD may be supplied with a signal (e.g., a driving signal and/or the like) provided by the drive circuit portion CB through the connection portion COM. The pad portion PD may be electrically connected to the connection part COM.

The signal supplied to the pad portion PD through the connection portion COM may be applied to the pixel PXL through wirings. A pixel PXL (e.g., a light-emitting element LD) may emit light based on an applied signal.

The pad portion PD may be referred to as a pad terminal.

The pad portion PD may include a plurality of pad portions PD. The plurality of pad portions PD may be formed or provided on a side of the display area DA. The plurality of pad portions PD may be sequentially arranged or provided in a direction. According to one or more embodiments, the plurality of pad portions PD may be arranged or provided in a matrix structure. The number and arrangement structure of the plurality of pad portions PD is not limited to the disclosed embodiments.

The pad portion PD may have a structure including a plurality of layers. More details thereof will be described herein with reference to the drawings after FIG. 3.

The connection portion COM may be disposed or provided in the non-display area NDA. At least a portion of the connection portion COM may be disposed or provided on the pad portion PD in the non-display area NDA.

A portion of the connection portion COM may be electrically connected to the drive circuit portion CB, and another portion of the connection portion COM may be electrically connected to the pad portion PD.

At least a portion of the connection portion COM may be bent and at least a portion of the connection portion COM may be disposed or provided on the back surface of the base layer BSL. The drive circuit portion CB connected to a portion of the connection portion COM may thus be disposed or provided on the back side of the base layer BSL.

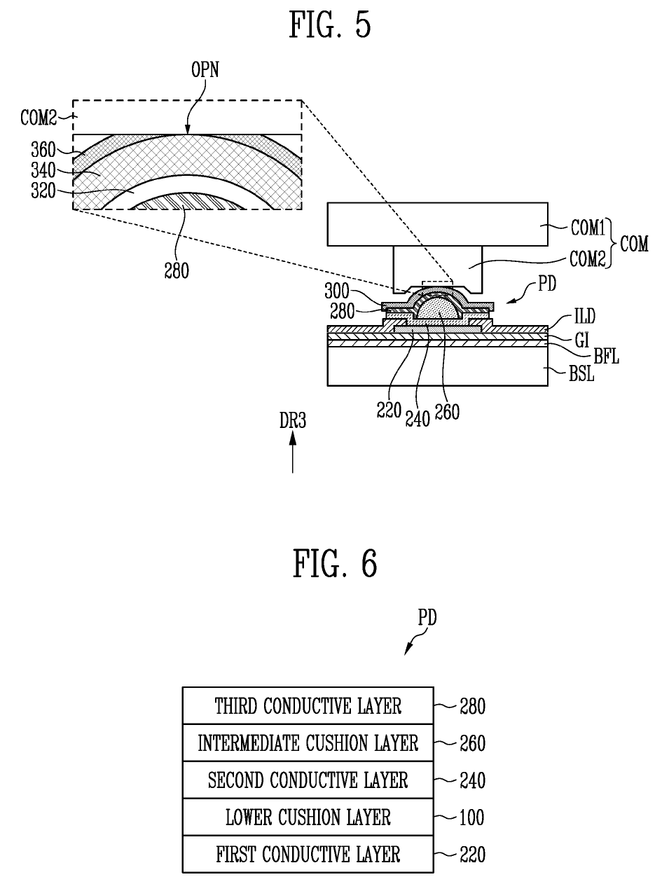

The connection portion COM may include a drive integrated circuit (a drive IC) COM1 (see FIG. 5) and a connection member COM2.

The drive IC COM1 may be implemented in one or more suitable ways. For example, the drive IC COM1 may have a chip-on-film structure. However, embodiments of the present disclosure are not limited thereto. The connection member COM2 may be formed or provided on a side of the drive IC COM1. The connection member COM2 may be electrically connected to the pad portion PD. Accordingly, the signal provided by the drive circuit portion CB may be provided to the pad portion PD through the drive IC COM1 and the connection member COM2.

According to one or more embodiments, the connection member COM2 may have a conductive (e.g., electrically conductive) bump or a lead structure. For example, the connection member COM2 may be a driving terminal or a protruding terminal patterned on the drive IC COM1. The connection member COM2 may be a wiring or signal line patterned on the drive IC COM1.

The drive circuit portion CB may be connected (e.g., electrically connected) to a portion of the connection portion COM. For ease of explanation, FIG. 2 illustrates a structure in which the connection portion COM is not bent, but may be disposed or provided on the back surface of the base layer BSL as the connection portion COM bends.

The drive circuit portion CB may supply an electrical signal (e.g., data, a driving signal, and/or the like) to control the operation of the pixel PXL to the pad portion PD through the drive IC COM1 and the connection member COM2.

According to one or more embodiments, the display device DD may further include a circuit layer CIL and a light-emitting element layer LEL disposed or provided on the base layer BSL in the display area DA.

The circuit layer CIL may include circuit elements (e.g., transistors and/or the like) electrically connected to pixel PXL (or light-emitting element LD).

The light-emitting element layer LEL may include a light-emitting element LD that emits light. The light-emitting element LD may include an organic light-emitting diode (OLED), an inorganic light-emitting diode (ILED), and/or the like. However, embodiments of the present disclosure are not limited thereto.

With reference to FIGS. 3 to 5, a pad portion PD and a connection portion COM according to one or more embodiments will be described herein in more detail. For convenience of explanation, any content that overlaps with the foregoing may be briefly described or may not be repeated.

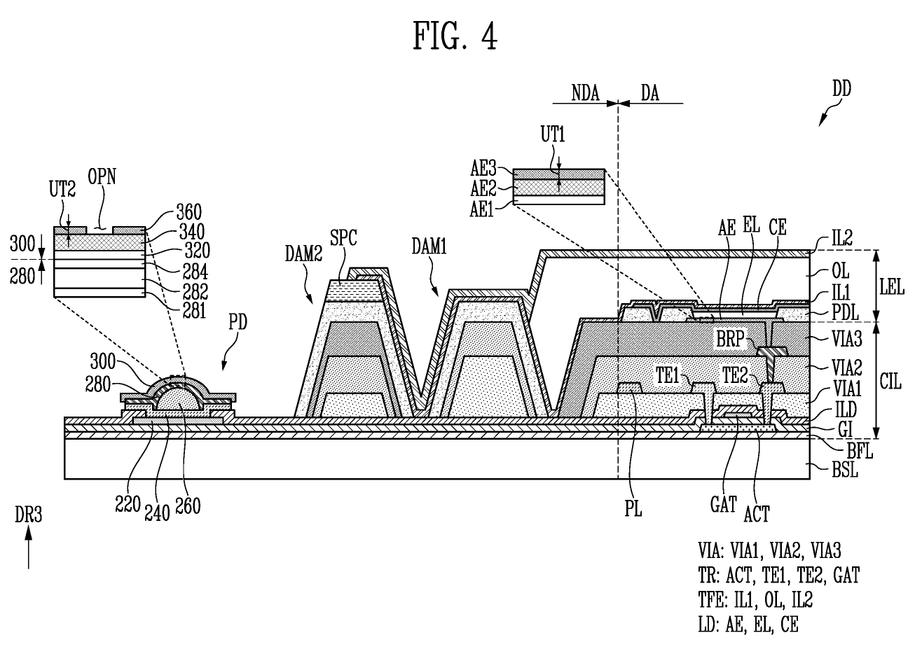

FIG. 3 is a schematic cross-sectional view illustrating a pad portion according to one or more embodiments. FIG. 4 is a schematic cross-sectional view illustrating a display device including a pad according to one or more embodiments. FIG. 5 is a schematic diagram illustrating an electrical connection structure between a pad portion and a connection portion according to one or more embodiments.

Referring to FIGS. 3 to 5, a pad portion PD according to one or more embodiments may include a plurality of layers. For example, the pad portion PD may include a first conductive layer 220, a second conductive layer 240, an intermediate cushion layer 260, and a third conductive layer 280. The pad portion PD may further include an upper connection layer 300.

According to one or more embodiments, the pad portion PD may be electrically connected to the connection portion COM through the upper connection layer 300. For example, the first conductive layer 220, the second conductive layer 240, the third conductive layer 280, and the upper connection layer 300 may be electrically connected to each other. For example, an intermediate cushion layer 260 may be between the second conductive layer 240 and the third conductive layer 280, and the second conductive layer 140 and the third conductive layer 280 may be electrically connected to each other through a region in which the intermediate cushion layer 280 is not disposed or provided.

The electrical signal provided by the connection portion COM to the upper connection layer 300 may be applied to the first to third conductive layers 220, 240, and 280, and may be applied to other components in the display device DD, such as the pixel PXL, through wiring electrically connected to at least one or more selected from among the first to third conductive layers 220, 240, and 280.

According to one or more embodiments, the intermediate cushion layer 260 may be formed or provided inside a terminal that forms or provides the pad portion PD. For example, the intermediate cushion layer 260 may be disposed or provided between two selected ones of the first through third conductive layers 220, 240, and 280. For example, the intermediate cushion layer 260 may be disposed or provided between the second conductive layer 240 and the third conductive layer 280. However, embodiments of the present disclosure are not limited thereto.

According to one or more embodiments, the intermediate cushion layer 260 may have elasticity. The intermediate cushion layer 260 may provide a cushioning function. For example, the intermediate cushion layer 260 may have greater elasticity than the first to third conductive layers 220, 240, and 280. The intermediate cushion layer 260 may have a smaller modulus than the first to third conductive layers 220, 240, and 280. For example, the intermediate cushion layer 260 may include an organic material.

According to one or more embodiments, the organic material herein may include one or more selected from among an acrylic resin, an epoxy resin, a phenol resin, a polyamide resin, a polyimide resin, a polyester resin, a polyphenylene sulfide resin, and/or a benzocyclobutene (BCB) resin. However, embodiments of the present disclosure are not limited thereto.

According to one or more embodiments, the intermediate cushion layer 260 may have a shape having a curvature (e.g., a cross-sectional shape). The intermediate cushion layer 260 may have a semi-ellipsoidal shape (e.g., a substantially semi-ellipsoidal shape). The intermediate cushion layer 260 may have a circular (e.g., substantially circular), elliptical (e.g., substantially elliptical), or polygonal (e.g., substantially polygonal) shape in plan view. However, embodiments of the present disclosure are not limited thereto.

According to one or more embodiments, the intermediate cushion layer 260 may have elastic properties (e.g., cushioning properties or small modulus properties) and may be provided with a feature as the intermediate cushion layer 260 has a curvature pattern. For example, the intermediate cushion layer 260 may maintain stability of electrical connection in the pad portion PD through a physical buffering role between the (2-3)th conductive layers 240 and 280 and prevent electrical connection failure (or reduce a degree or occurrence of electrical connection failure) through a curvature pattern. In one or more embodiments, the intermediate cushion layer 260 may disperse the pressure that may be generated in the pad portion PD, absorb vibrations and/or shocks to prevent physical damage (or reduce a degree or occurrence of physical damage) to the pad portion PD and prevent moisture absorption and/or interface peeling (or reduce moisture absorption and/or interface peeling) to improve or enhance the reliability of the pad portion PD. Also, spacing between pad portions PD (e.g., pad terminals) may be maintained.

According to one or more embodiments, the first conductive layer 220, the second conductive layer 240, the intermediate cushion layer 260, the third conductive layer 280, and the upper connection layer 300 may be patterned in a same or substantially the same process as the conductive layer or the insulating layer patterned in the display area DA. Accordingly, the process methods to form or provide the pad portion PD may be simplified.

According to one or more embodiments, an upper connection layer 300 may be formed or provided on top of the pad portion PD. For example, the upper connection layer 300 may be the uppermost structure of the pad terminal formed or provided by the pad portion PD and may be connected (e.g., electrically connected) to the connection member COM2.

According to one or more embodiments, the upper connection layer 300 may be in contact with the connection member COM2, and the connection member COM2 may be spaced and/or apart (e.g., spaced apart or separated) from the third conductive layer 280. In one or more embodiments, the pad portion PD may have fine chemical resistance characteristics (or resistance to fine chemicals). For example, the resistance of the pad terminal of the pad portion PD may be reduced, and the reliability of the pad portion PC may be improved or enhanced. More details of this aspect and feature of the present disclosure will be described herein.

With further reference to FIGS. 4 and 5, a display device DD according to one or more embodiments will be described in more detail in combination with other components of the display device DD and the pad portion PD including the upper connection layer 300.

According to one or more embodiments, the display device DD (e.g., the circuit layer CIL) may include a base layer BSL, a buffer layer BFL, an active layer ACT, a gate insulating layer GI, a gate conductive layer GAT, an interlayer insulating layer ILD, a via layer VIA, a power line PL, first and second transistor electrode layers TE1 and TE2, and a bridge layer BRP. The via layer VIA may include a first via layer VIA1, a second via layer VIA2, and a third via layer VIA3. The circuit layer CIL may include a transistor TR. The transistor TR may include an active layer ACT, a gate conductive layer GAT, a first transistor electrode layer TE1, and a second transistor electrode layer TE2.

According to one or more embodiments, the display device DD (e.g., the light-emitting element layer LEL) may include a light-emitting element LD, a pixel defining layer PDL, and an encapsulation layer TFE.

According to one or more embodiments, the display device DD may include a first dam DAM1 and a second dam DAM2.

The base layer BSL may be formed or provided over the display area DA and the non-display area NDA. The base layer BSL may provide a base on which the pad portion PD, the circuit layer CIL, and the light-emitting element layer LEL are disposed or provided.

The buffer layer BFL may be disposed or provided over the display area DA and the non-display area NDA and may be disposed or provided on the base layer BSL. The buffer layer BFL may be disposed or provided between the active layer ACT and the base layer BSL. According to one or more embodiments, the buffer layer BFL may include an inorganic material.

The active layer ACT may be disposed or provided on the buffer layer BFL in the display area DA. The active layer ACT may include one or more suitable semiconductor materials. For example, the active layer ACT may include one or more selected from among polysilicon, low temperature polycrystalline silicon (LTPS), amorphous (e.g., non-crystalline) silicon, and/or an oxide semiconductor. However, embodiments of the present disclosure are not limited thereto.

The gate insulating layer GI may be disposed or provided on the buffer layer BFL across the display area DA and the non-display area NDA and may cover the active layer ACT. The gate insulating layer GI may include an inorganic material. At least a portion of the gate insulating layer GI may be disposed or provided between the gate conductive layer GAT and the active layer ACT.

The gate conductive layer GAT may be disposed or provided on the gate insulating layer GI in the display area DA and may overlap the active layer ACT in plan view. The gate conductive layer GAT may include one or more suitable conductive materials (e.g., electrically conductive materials). For example, the gate conductive layer GAT may include one or more of a group selected from among gold (Au), silver (Ag), aluminum (Al), molybdenum (Mo), chromium (Cr), titanium (Ti), nickel (Ni), neodymium (Nd), copper (Cu), and platinum (Pt). However, embodiments of the present disclosure are not limited thereto.

The first conductive layer 220 may be disposed or provided on the base layer BSL (e.g., the gate insulating layer GI or the buffer layer BFL) in the non-display area NDA. According to one or more embodiments, the first conductive layer 220 may form or provide a bottom portion of the pad portion PD (e.g., a pad terminal). The first conductive layer 220 may be patterned in a same or substantially the same process as the gate conductive layer GAT and may include a same or substantially the same conductive material (e.g., electrically conductive material) as the gate conductive layers GAT.

The interlayer insulating layer ILD may be disposed or provided on the gate insulating layer GI over the display area DA and the non-display area NDA. The interlayer insulating layer ILD may cover the gate conductive layer GAT and may cover a portion of the first conductive layer 220. The interlayer insulating layer ILD may expose a portion of the upper surface of the first conductive layer 220. The interlayer insulating layer ILD may include an inorganic material.

The first via layer VIA1 may be disposed or provided in the display area DA and may be disposed or provided on the interlayer insulating layer ILD. The first via layer VIA1 may cover the gate conductive layer GAT. The first via layer VIA1 may include an organic material.

The first and second transistor electrodes TE1 and TE2 may be disposed or provided on the first via layer VIA1 in the display area DA and may be electrically connected to the active layer ACT through a contact member that penetrates through the first via layer VIA1, respectively. The first and second transistor electrodes TE1 and TE2 may be a source electrode and a drain electrode, respectively, or may be a drain electrode and a source electrode.

The power line PL may be disposed or provided on the first via layer VIA1 in the display area DA. The power line PL may be configured or provided to supply power to the light-emitting element LD.

The first and second transistor electrodes TE1 and TE2 and power line PL may be patterned in a same or substantially the same process as each other and may include a same or substantially the same conductive material (e.g., electrically conductive material). For example, the first and second transistor electrodes TE1 and TE2 and power line PL may include one or more of the group selected from among gold (Au), silver (Ag), aluminum (Al), molybdenum (Mo), chromium (Cr), titanium (Ti), nickel (Ni), neodymium (Nd), copper (Cu), and platinum (Pt). However, embodiments of the present disclosure are not limited thereto.

The second conductive layer 240 may be disposed or provided on the first conductive layer 220 in the non-display area NDA. The second conductive layer 240 may cover a portion of an interlayer insulating layer ILD that covers the first conductive layer 220. According to one or more embodiments, the second conductive layer 240 may be in contact with a portion of the first conductive layer 220 exposed by the interlayer insulating layer ILD.

The second conductive layer 240 may be disposed or provided under the intermediate cushion layer 260. The second conductive layer 240 may support the intermediate cushion layer 260 at a lower portion of the intermediate cushion layer 360.

The second conductive layer 240 may be patterned in a same or substantially the same process as the first and second transistor electrode layers TE1 and TE2 and may include a same or substantially the same conductive material (e.g., electrically conductive material) as the first and the second transistor electrode layers TE1 and TE2.

The second via layer VIA2 may be disposed or provided in the display area DA and may be disposed or provided on the first via layer VIA1. The second via layer VIA2 may cover at least a portion of the first and second transistor electrodes TE1 and TE2. The second via layer VIA2 may include an organic material.

The intermediate cushion layer 260 may be disposed or provided on the second conductive layer 240 in the non-display area NDA. The intermediate cushion layer 260 may overlap a region where the first and second conductive layers 220 and 240 contact each other in plan view.

The intermediate cushion layer 260 may have a cross-sectional shape that protrudes in a thickness direction (e.g., the third direction DR3) of the base layer BSL. The intermediate cushion layer 260 may have a hemispherical cross-sectional shape (e.g., a substantially hemispherical cross-sectional shape). However, embodiments of the present disclosure are not limited thereto.

The intermediate cushion layer 260 may be patterned in a same or substantially the same process as the second via layer VIA2 and may include a same or substantially the same material (e.g., material that forms or provides the elastic/cushion) as each other. For example, the intermediate cushion layer 260 may include a same or substantially the same organic material as the second via layer VIA2. As described in one or more embodiments, the intermediate cushion layer 260 may be configured or provided to perform a cushioning function, thereby improving or enhancing physical stability of the pad portion PD and improving or enhancing electrical connection reliability.

The bridge layer BRP may be disposed or provided on the second via layer VIA2 in the display area DA. The bridge layer BRP may be electrically connected to the second transistor electrode TE2 through a contact member that penetrates the second via layer VIA2.

The third conductive layer 280 may be disposed or provided on the intermediate cushion layer 260 and may cover the second conductive layer 240. For example, the third conductive layer 280 may contact a portion of the second conductive layer 240 exposed by the intermediate cushion layer 260. Accordingly, the first to third conductive layers 220, 240, and 280 may be electrically connected to each other.

The bridge layer BRP and the third conductive layer 280 may be patterned in a same or substantially the same process as each other and may include a same or substantially the same conductive material (e.g., electrically conductive material). For example, the first and second transistor electrodes TE1 and TE2, and power line PL may include one or more of the group selected from among gold (Au), silver (Ag), aluminum (Al), molybdenum (Mo), chromium (Cr), titanium (Ti), nickel (Ni), neodymium (Nd), copper (Cu), and platinum (Pt). However, embodiments of the present disclosure are not limited thereto.

According to one or more embodiments, the third conductive layer 280 may have a multilayer structure. For example, the third conductive layer 280 may include a (3-1)th conductive layer 281, a (3-2)th conductive layer 282 disposed or provided on the (3-1)th conductive layer 281, and a (3-3)th conductive layer 284 disposed or provided on the (3-2)th conductive layer 282. A lower surface of the (3-2)th conductive layer 282 may be in contact with the (3-1)th conductive layer 281, and an upper surface of the (3-2)th conductive layer 282 may be in contact with the (3-3)th conductive layer 284. According to one or more embodiments, the (3-3)th conductive layer 284 may be a top layer of the third conductive layer 280 and may be a layer directly adjacent to the upper connection layer 300. According to one or more embodiments, the top surface of the (3-3)th conductive layer 284 may not be exposed. According to one or more embodiments, the top surface of the (3-2)th conductive layer 282 may not be exposed by the (3-3)th conductive layer 284.

According to one or more embodiments, the (3-1)th conductive layer 281 and the (3-3)th conductive layer 284 may have fine chemical resistance (or resistance to fine chemicals). For example, the (3-1)th and (3-3)th conductive layers 281 and 284 may include titanium (Ti). The (3-2)th conductive layer 282 may have a low electrical conductivity and may have a greater thickness (or thicker) than the (3-1)th conductive layer 281 and the (3-3)th conductive layer 284. For example, the (3-2)th conductive layer 282 may include aluminum (Al).

According to one or more embodiments, the (2-3)th conductive layers 240 and 280 may have ends that overlap each other in plan view.

The third via layer VIA3 may be disposed or provided in the display area DA and may be disposed or provided on the second via layer VIA2. The third via layer VIA3 may cover at least a portion of the bridge layer BRP. The third via layer VIA3 may include an organic material.

The light-emitting element LD may be disposed or provided on the third via layer VIA3. The light-emitting element LD may include a first electrode AE, a light-emitting layer EL, and a second electrode CE.

The first electrode AE may be disposed or provided on the third via layer VIA3 in the display area DA. The first electrode AE may be electrically connected to the bridge layer BRP through a contact member that penetrates the third via layer VIA3. The first electrode AE may be an anode electrode.

The first electrode AE may include a multilayer structure and may include one or more suitable conductive materials (e.g., electrically conductive materials). For example, the first electrode AE may include a (1-1)th electrode AE1, a (1-2)th electrode AE2 on the (1-1)th electrode AE1, and a (1-3)th electrode AE3 on the (1-2)th electrode AE2.

The upper connection layer 300 may be disposed or provided (e.g., directly disposed or provided) on the third conductive layer 280 in the non-display area NDA. The upper connection layer 300 may entirely (e.g., substantially entirely) cover the upper surface of the third conductive layer 280 and may cover at least a portion of an end portion (e.g., a side end portion) of the third conductive layer 280.

The upper connection layer 300 may include a multilayer structure and may include one or more suitable conductive materials (e.g., electrically conductive materials). For example, the upper connection layer 300 may include a first upper connection layer 320, a second upper connection layer 340, and a third upper connection layer 360.

According to one or more embodiments, the third upper connection layer 360 may form or provide an opening OPN. The third upper connection layer 360 may expose a portion of the top surface of the second upper connection layer 340.

According to one or more embodiments, the first upper connection layer 320 may prevent oxidation of layers (or reduce a degree or occurrence of oxidation of layers) disposed or provided below (e.g., the first to third conductive layers 220, 240, and 280) and allow the layers of the pad terminal of the pad portion PD to be suitably adhered to each other.

According to one or more embodiments, the second upper connection layer 340 may stably couple the first and third upper connection layers 320 and 360 and may contact the connection member COM2 through the opening OPN to form or provide a stable and reliable electrical connection path. According to one or more embodiments, the connection member COM2 may be in contact with the second upper connection layer 340 exposed by the opening OPN and may not be in contact with another portion of the second upper connection layers 340 covered by the third upper connection layer 360. According to one or more embodiments, the (1-3)th electrode AE3 may cover an entire (e.g., substantially entire) top surface of the (1-2)th electrode AE2 and may not expose the top surface of the (1-2)th electrode AE2, respectively.

According to one or more embodiments, the third upper connection layer 360 may function as a protective layer, such as covering layers disposed or provided under the third upper connection layers 360 to prevent oxidation (or reduce a degree or occurrence of oxidation). For example, the third upper connection layer 360 may be a capping layer for the first and second upper connection layers 320 and 340.

According to one or more embodiments, the upper connection layer 300 and the first electrode AE may be patterned in a same or substantially the same process as each other and may include a same or substantially the same conductive material (e.g., electrically conductive material) as each other. For example, the (1-1)th electrode AE1 and the first upper connection layer 320 may be patterned in a same or substantially the same process as each other and may include a same or substantially the same conductive material (e.g., electrically conductive material) as each other. The (1-2)th electrode AE2 and the second upper connection layer 340 may be patterned in a same or substantially the same process and may include a same or substantially the same conductive material (e.g., electrically conductive material). The (1-3)th electrode AE3 and the third upper connection layer 360 may be patterned in a same or substantially the same process and may include a same or substantially the same conductive material (e.g., electrically conductive material).

According to one or more embodiments, the (1-1)th electrode AE1 and the first upper connection layer 320 may include a same or substantially the same transparent (e.g., substantially transparent) conductive (e.g., electrically conductive) material, the (1-2)th electrode AE2 and the second upper connection layer 340 may include a same or substantially the same reflective (e.g., substantially reflective) conductive (e.g., electrically conductive) material, and the (1-3)th electrode AE3 and the third upper connection layer 360 may include a same or substantially the same transparent (e.g., substantially transparent) conductive (e.g., electrically conductive) material.

For example, the (1-1)th electrode AE1 and the first upper connection layer 320 may include indium tin oxide (ITO), the (1-2)th electrode AE2 and the second upper connection layer 340 may include one or more selected from among gold (Au), silver (Ag), aluminum (Al), copper (Cu), and nickel (Ni) as a same or substantially the same reflective (e.g., substantially reflective) conductive (e.g., electrically conductive) material, and the (1-3)th electrode AE3 and the third upper connection layer 360 may include indium tin oxide (ITO).

However, embodiments of the present disclosure are not limited thereto. According to one or more embodiments, the (1-1)th electrode AE1 and the first upper connection layer 320 may include a same or substantially the same reflective (e.g., substantially reflective) conductive (e.g., electrically conductive) material, the (1-2)th electrode AE2 and the second upper connection layer 340 may include a same or substantially the same reflective (e.g., substantially reflective) conductive (e.g., electrically conductive) material, and the (1-3)th electrode AE3 and the third upper connection layer 360 may include a same or substantially the same reflective (e.g., substantially reflective) conductive (e.g., electrically conductive) material.

For example, the (1-1)th electrode AE1 and the first upper connection layer 320 may include one or more selected from among gold (Au), silver (Ag), aluminum (Al), copper (Cu), and nickel (Ni) as a same or substantially the same reflective (e.g., substantially reflective) conductive (e.g., electrically conductive) material, the (1-2)th electrode AE2 and the second upper connection layer 340 may include one or more selected from among gold (Au), silver (Ag), aluminum (Al), copper (Cu), and nickel (Ny) as a same or substantially the same reflective (e.g., substantially reflective) conductive (e.g., electrically conductive) material, and the (1-3)th electrode AE3 and the third upper connection layer 360 may include one or more selected from among gold (Au), silver (Ag), aluminum (Al), copper (Cu), and nickel (Ni) as a same or substantially the same reflective (e.g., substantially reflective) conductive (e.g., electrically conductive) material.

According to one or more embodiments, the connection member COM2 may contact the second upper connection layer 340, and a portion of the connection member COM2 may contact the third upper connection layer 360. According to one or more embodiments, the third upper connection layer 360 may be adhered to the connection member COM2 and the pad portion PD. According to one or more embodiments, a third upper connection layer 340 made or composed of a transparent (e.g., substantially transparent) conductive (e.g., electrically conductive) material, such as ITO, may be disposed or provided on top of the pad portion PD, and the third upper connection layer 240 may be formed or provided in a same or substantially the same process as the first electrode AE. As a result, the process methods may be simplified and the adhesive properties between the pad portion PD and the connection member COM2 may be improved or enhanced.

According to one or more embodiments, the (1-1)th electrode AE1 and the first upper connection layer 320 may have a same or substantially the same thickness. For example, the (1-1)th electrode AE1 and the first upper connection layer 320 may have a thickness of about 10 Å to about 300 Å. In one or more embodiments, the first upper connection layer 320 may stably cap the third conductive layer 280 (or the upper surface of the (3-3)th conductive layer 284).

According to one or more embodiments, the (1-2)th electrode AE2 and the second upper connection layer 340 may have a same or substantially the same thickness as each other. For example, the (1-2)th electrode AE2 and the second upper connection layer 340 may have a thickness of about 500 Å to about 10000 Å. In one or more embodiments, the second upper connection layer 340 may form or provide a stable electrical connection structure between the first and third upper connection layers 320 and 360.

According to one or more embodiments, the (1-3)th electrode AE3 and the third upper connection layer 360 may have different thicknesses.

The (1-3)th electrode AE3 may have a first thickness TK1. The third upper connection layer 360 may have a second thickness TK2 that is less than the first thickness TK1. According to one or more embodiments, the second thickness TK2 may be between about 10 Å and about 300 Å, and the first thickness TK1 may have a value greater than the second thickness TK2 as described herein.

According to one or more embodiments, the third upper connection layer 360 may be a top layer of the upper connection layer 300. The (1-3)th electrode AE3 may be the top layer of the first electrode AE. According to one or more embodiments, after patterning the first electrode AE and the upper connection layer 300, if (e.g., when) processes of patterning other layers (e.g., a deposition and etching process and/or the like) are performed, an upper surface of the third upper connection layer 360 may be exposed, and an upper surface of a (1-3)th electrode AE3 may be covered by the light-emitting layer EL. In one or more embodiments, a part of the third upper connection layer 360 may be removed (e.g., consume) to reduce the thickness, and the thickness of the (1-3)th electrodes AE3 may be relatively maintained during the process of patterning other layers (e.g., a deposition and etching process and/or the like). Accordingly, the third upper connection layer 360 and the (1-3)th electrode AE3 may be patterned in a same or substantially the same process, but may be manufactured to have different thicknesses from each other.

According to one or more embodiments, as the third upper connection layer 360 has a thickness smaller than the (1-3)th electrodes AE3, if (e.g., when) the connection member COM2 is disposed or provided on the upper connection layer 300 to couple the connection members COM2 and the pad portions PD, a portion of the third upper connection layers 360 may be structurally changed to form or provide the openings OPN due to the pressure applied by the connection members COM2. According to one or more embodiments, as the connection member COM2 is provided on the upper connection layer 300, the second upper connection layer 340 may be exposed, and the connection member COM2 and the second upper connection layers 340 may be in physical contact with each other. According to one or more embodiments, the top of the curved surface formed or provided by the second upper connection layer 340 may be in contact with the connection member COM2.

According to one or more embodiments, the upper connection layer 300 may be between the connection member COM2 and the third conductive layer 280, and the connection member COM2 may not be directly adjacent to the third conductive layer 180. According to one or more embodiments, aluminum (Al) may be included such that the resistance (e.g., the electrical resistance) of the first and second transistor electrodes TE1 and TE2 and the third conductive layer 280 is reduced. In one or more embodiments, aluminum (Al) may form oxides due to its high reactivity (e.g., high chemical reactivity), and there may be a risk of damaging the resistance (e.g., electrical resistance) characteristics. However, according to one or more embodiments, after the upper connection layer 300 is disposed or provided on the third conductive layer 280 including aluminum (Al), a process of coupling the pad portion PD and the connection member COM2 may proceed.

Accordingly, an oxide may be formed or provided in a portion of the pad portion PD, such that the reliability of the electrical connection may be improved or enhanced. In one or more embodiments, the second upper connection layer 340 including silver (Ag) and/or the like in the upper connection layer 300 may be connected to the connection member COM2, and the second upper connection layers 340 may be protected by the third upper connection layer 360, such that a risk, such as formation of oxide and/or the like in a portion of the pad portion PD, may be reduced.

The pixel defining layer PDL may be disposed or provided in the display area DA and may cover the first electrode AE. The pixel defining layer PDL may define a region where the light-emitting layer EL and the first electrode AE are electrically connected. The pixel defining layer PDL may include an inorganic material and/or an organic material. According to one or more embodiments, the pixel defining layer PDL may have a single-layer structure or a multi-layer structure.

The light-emitting layer EL may be disposed or provided on the first electrode AE in the display area DA and may be electrically connected between the first electrode AE and the second electrode CE. According to one or more embodiments, the light-emitting layer EL may emit different colors depending on the corresponding sub-pixel SPX. For example, the light-emitting layer EL included in the first sub-pixel SPX1 may emit light of a first color, the light-emitting layer EL included the second sub-pixel SPX2 may emit light of a second color, and the light-emitting layers EL included in third sub-pixels SPX3 may emit light of a third color.

The light-emitting layer EL may be manufactured based on one or more suitable process methods, such as a vapor deposition process and/or a coating process. The light-emitting layer EL may include a plurality of layers. For example, the light-emitting layer EL may include a hole transport portion, an emission portion (or a light-generating layer), and an electron transport portion. Each of the layers that form or provide the light-emitting layer EL may include an organic material and may further include a metal-including compound, an inorganic material, such as quantum dots, and/or the like, according to one or more embodiments.

The cathode electrode CE may be disposed or provided on the pixel defining layer PDL and the light-emitting layer EL in the display area DA. The cathode electrode CE may include one or more suitable conductive materials (e.g., electrically conductive materials). For example, the cathode electrode CE may include silver (Ag) and may further include an additional metal. The additional metal may include one or more selected from among magnesium (Mg), aluminum (Al), copper (Cu), calcium (Ca), and barium (Ba). For example, the cathode electrode CE may include a silver-magnesium (AgMg) alloy. However, embodiments of the present disclosure are not limited thereto. According to one or more embodiments, the cathode electrode CE may include one or more suitable transparent (e.g., substantially transparent) conductive (e.g., electrically conductive) materials. The second electrode CE may be a cathode electrode. The second electrode CE may be a common electrode for the light-emitting elements LD of each of the sub-pixels SPX.

The first dam DAM1 may be disposed or provided in the non-display area NDA and may protrude in the thickness direction of the base layer BSL. The first dam DAM1 may be around (e.g., surround) the periphery of the display area DA. The first dam DAM1 may include a layer formed or provided in a same or substantially the same process as the first via layer VIA1, a layer formed or provided in a same or substantially the same process as the second via layer VIA2, and a layer formed or provided in a same or substantially the same process as the pixel defining layer PDL.

The second dam DAM2 may be disposed or provided in the non-display area NDA and may protrude in the direction of the thickness of the base layer BSL. The second dam DAM2 may be around (e.g., surround) the periphery of the display area DA. The second dam DAM2 may include a layer formed or provided in a same or substantially the same process as the first via layer VIA1, a layer formed or provided in a same or substantially the same process as the second via layer VIA2, a layer formed or provided in another process (e.g., in a same or substantially the same process) as the third via layer VIA3, a layer formed or provided in a same or substantially the same process as the pixel defining layer PDL, and a spacer SPC.

The encapsulation layer TFE may cover the light-emitting element LD. The encapsulation layer TFE may include a first encapsulation layer IL1, a second encapsulation layer OL, and a third encapsulation layer IL2.

The first encapsulation layer IL1 may be disposed or provided over the display area DA and the non-display area NDA and may cover the cathode electrode CE, the first dam DAM1, and the second dam DAM2. The first encapsulation layer IL1 may include an inorganic material.

The second encapsulation layer OL may be disposed or provided over the display area DA and the non-display area NDA, may be disposed or provided on the first encapsulation layer IL1, and may be provided in an area surrounded by the first dam DAM1. The second encapsulation layer OL may include an organic material.

The third encapsulation layer IL3 may be disposed or provided over the display area DA and the non-display area NDA and may cover the second encapsulation layer OL, the first dam DAM1, and the second dam DAM2. The third encapsulation layer IL3 may include an inorganic material.

With reference to FIGS. 6 to 11, a pad portion PD and a connection portion COM according to one or more embodiments will be described herein in more detail. For convenience of explanation, any content that overlaps with the foregoing may be briefly described or may not be repeated.

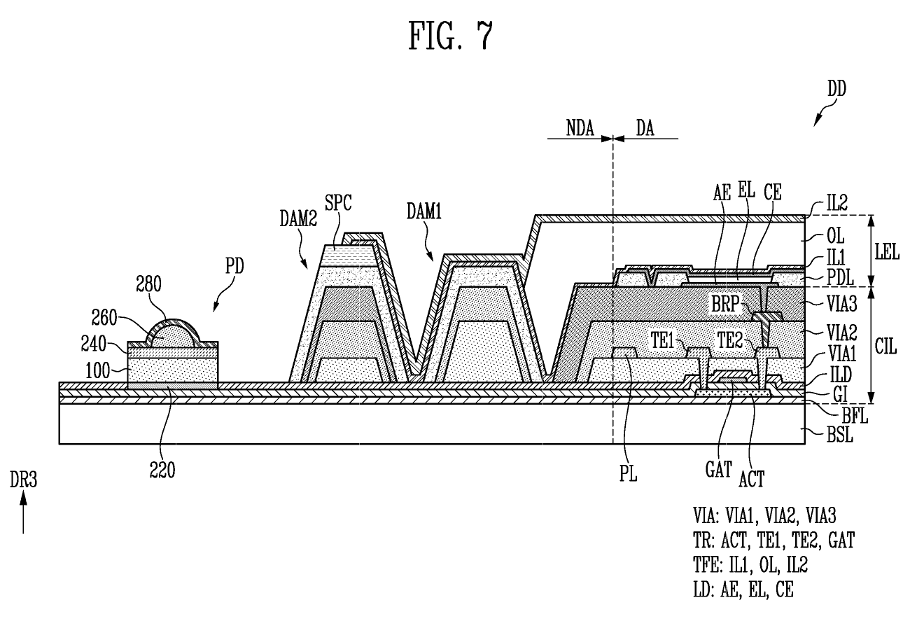

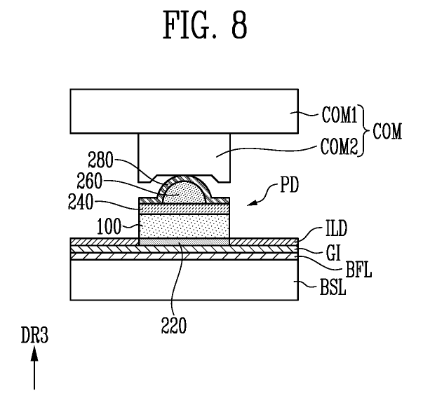

FIG. 6 is a schematic cross-sectional view illustrating a pad portion according to one or more embodiments. FIGS. 7 and 9 to 11 are schematic cross-sectional views illustrating a display device including a pad portion according to one or more embodiments. FIG. 8 is a schematic diagram illustrating an electrical connection structure between a pad portion and a connection portion according to one or more embodiments.

Referring to FIG. 6, the pad portion PD according to the present embodiment may be different from the pad portion PD as described in one or more embodiments with reference to FIGS. 3 to 5 in that the pad portion PD may further include the lower cushion layer 100 and may not include the upper connection layer 300.

According to one or more embodiments, the pad portion PD may be electrically connected to the connection portion COM (e.g., the connection member COM2) through the third conductive layer 280. The third conductive layer 280 may be in contact with a connection portion COM (e.g., a connection member COM2). For example, the first conductive layer 220, the second conductive layer 240, and the third conductive layer 280 may be electrically connected to each other. For example, an intermediate cushion layer 260 may be between the second conductive layer 240 and the third conductive layer 280, and the second conductive layer 140 and the third conductive layer 280 may be electrically connected to each other through a region in which the intermediate cushion layer 280 is not disposed or provided. The lower cushion layer 100 may be between the first conductive layer 220 and the second conductive layer 240, and the first conductive layer 22 and the second conductive layer 240 may be electrically connected to each other through a region where the lower cushion layer 100 is not disposed or provided.

According to one or more embodiments, the lower cushion layer 100 may be formed or provided inside a terminal that forms or provides the pad portion PD. The lower cushion layer 100 may be disposed or provided between the first and second conductive layers 220 and 240. The lower cushion layer 100 may be disposed or provided below the intermediate cushion layer 260. For example, the lower cushion layer 100 may be closer to the base layer BSL than the intermediate cushion layer 260. The lower cushion layer 100 may be disposed or provided between the base layer BSL and the intermediate cushion layer 260.

According to one or more embodiments, the lower cushion layer 100 may have elasticity. The lower cushion layer 100 may provide a cushioning function. For example, the lower cushion layer 100 may have greater elasticity than the first to third conductive layers 220, 240, and 280. The lower cushion layer 100 may have a smaller modulus than the first to third conductive layers 220, 240, and 280. For example, the lower cushion layer 100 may include an organic material.

According to one or more embodiments, the lower cushion layer 100 may have a shape having a curvature (e.g., a cross-sectional shape). The lower cushion layer 100 may have a semi-ellipsoidal shape (e.g., a substantially semi-ellipsoidal shape). The lower cushion layer 100 may have a circular shape (e.g., a substantially circular shape), an elliptical shape (e.g., a substantially elliptical shape), or a polygonal shape (e.g., a substantially polygonal shape) in plan view. However, embodiments of the present disclosure are not limited thereto.

The lower cushion layer 100 may improve or enhance the reliability of the electrical connection and may serve as a physical buffer, similar to the intermediate cushion layer 260 as described in one or more embodiments.

According to one or more embodiments, the lower cushion layer 100 and the intermediate cushion layer 260 may be spaced and/or apart (e.g., spaced apart or separated) from each other. For example, a second conductive layer 240 may be between the lower cushion layer 100 and the intermediate cushion layer 260. Accordingly, the pad portion PD may be formed or provided with two or more cushion structures that are physically separated from each other.

The second conductive layer 240 may be between the lower cushion layer 100 and the intermediate cushion layer 260 to effectively or suitably support the pressure applied to the intermediate cushion layer 360. For example, the second conductive layer 240 may have a modulus greater than the intermediate cushion layer 260 and may be disposed or provided under the intermediate cushion layer 360 such that the intermediate cushion layer 160 is not excessively or substantially pressed. Therefore, the stress between the connection member COM2 and the third conductive layer 280 may increase, such that the connection member COM2 and the pad portion PD may be more closely coupled.

According to one or more embodiments, at least one selected from among the conductive layers may be disposed or provided between the lower cushion layer 100 and the intermediate cushion layer 260. For example, the lower cushion layer 100 may be disposed or provided under the second conductive layer 240, which may function as a support layer of the intermediate cushion layer 260. If (e.g., when) the coupling process between the connection member COM2 and the pad portion PD is performed, the lower cushion layer 100 may be efficiently or suitably restored after being pressed against the pad portion PD, thereby improving or enhancing the electrical connection reliability between the pad portion PD and the connection member COM2.

With reference to FIGS. 8 to 11, a display device DD according to one or more embodiments will be described herein in more detail in combination with the pad portion PD including the lower cushion layer 100 and other components of the display device DD. For convenience of explanation, any content that overlaps with the foregoing may be briefly described or may not be repeated.

Referring to FIGS. 7 and 8, the first conductive layer 220, the lower cushion layer 100, the second conductive layer 240, the intermediate cushion layer 260, and the third conductive layer 280 may be sequentially disposed or provided.

According to one or more embodiments, the first conductive layer 220 may be patterned in a same or substantially the same process as the gate conductive layer GAT and may include a same or substantially the same conductive material (e.g., electrically conductive material).

According to one or more embodiments, the lower cushion layer 100 may be patterned in a same or substantially the same process as the first via layer VIA1 and may include a same or substantially the same material (e.g., organic material) to have cushioning properties.

According to one or more embodiments, the second conductive layer 240 may be patterned in a same or substantially the same process as the first and second transistor electrodes TE1 and TE2 and may include a same or substantially the same conductive material (e.g., electrically conductive material).

According to one or more embodiments, the intermediate cushion layer 260 may be patterned in a same or substantially the same process as the second via layer VIA2 and may include a same or substantially the same material (e.g., organic material) to have cushioning properties.

According to one or more embodiments, the third conductive layer 280 may be patterned in a same or substantially the same process as the bridge layer BRP and may include a same or substantially the same conductive material (e.g., electrically conductive material).

According to one or more embodiments, the lower cushion layer 100 and the first conductive layer 220 may overlap each other in plan view and may have widths similar to each other. In one or more embodiments, the third conductive layer 280 may be disposed or provided on the intermediate cushion layer 260 having cushioning characteristics and may be in physical contact with the connection member COM2.

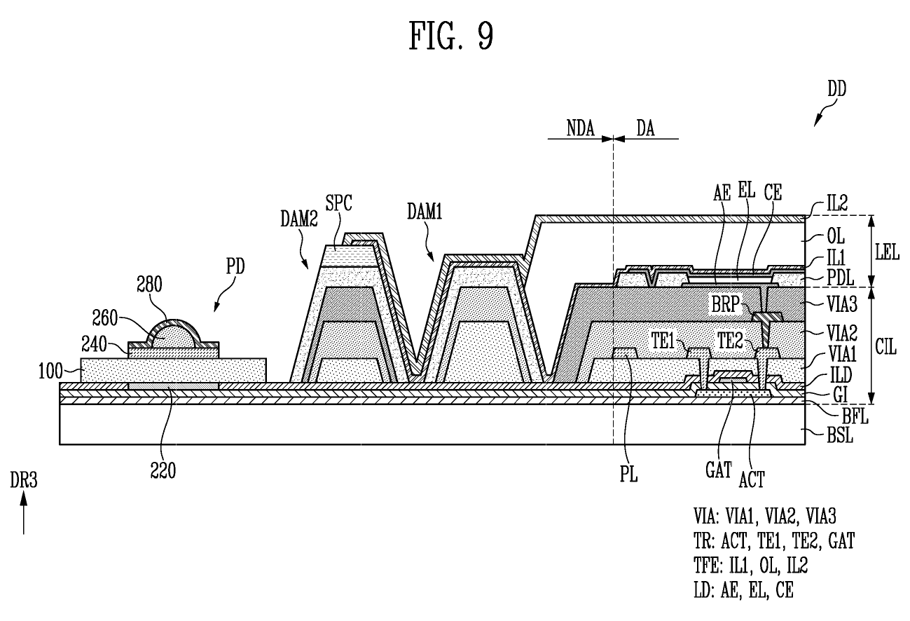

Referring to FIG. 9, the first conductive layer 220, the second conductive layer 240, the third conductive layer 280, and the intermediate cushion layer 260 may be disposed or provided inside a region where the lower cushion layer 100 is disposed or provided.

For example, the lower cushion layer 100 may be patterned to extend over a relatively large area. The lower cushion layer 100 may be further expanded relative to the edges of the first conductive layer 220, the second conductive layer 240, the third conductive layer 280, and the intermediate cushion layer 260.

According to the present disclosure, the lower cushion layer 100 may more effectively or suitably induce compression restoration by the connection member COM2.

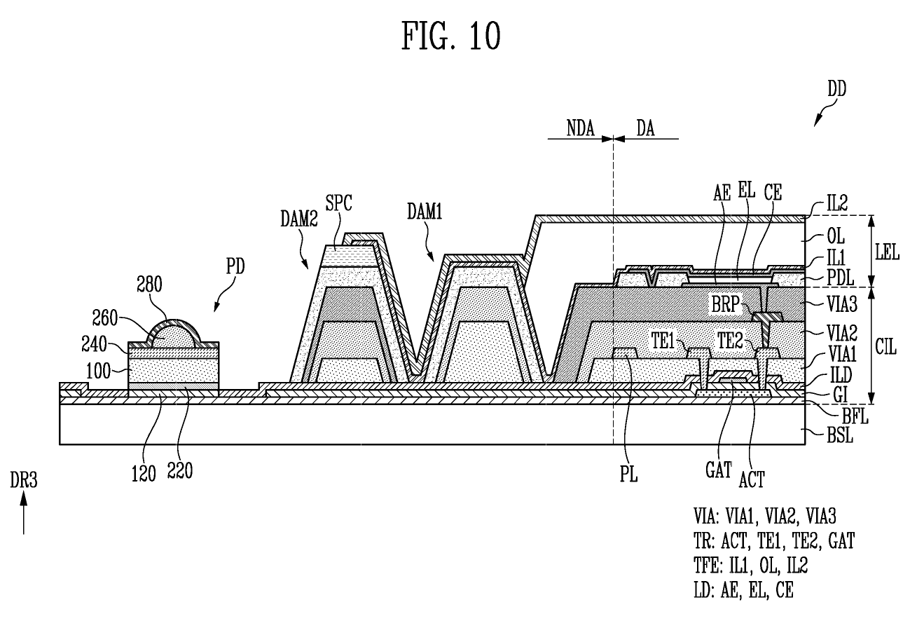

Referring to FIG. 10, the pad portion PD according to one or more embodiments may further include an additional lower cushion layer 120 formed or provided under the first conductive layer 220.

According to one or more embodiments, the further lower cushion layer 120 may be disposed or provided between the buffer layer BFL and the first conductive layer 220 in the non-display area NDA.

The additional lower cushion layer 120 may have a smaller modulus than the first conductive layer 220, and thus may have cushioning properties with respect to the first conductive layer 220. For example, the additional lower cushion layer 120 may include an inorganic material. For example, the additional lower cushion layer 120 may be patterned in a same or substantially the same process as the gate insulating layer GI and may include a same or substantially the same material. An additional lower cushion layer 120 may be disposed or provided between the first conductive layer 220 and the base layer BSL.

According to one or more embodiments, the pad portion PD may include an additional lower cushion layer 120, a lower cushion layer 100, and an intermediate cushion layer 260 spaced and/or apart (e.g., spaced apart or separated) from each other, with layers having a relatively large modulus between each layer. Accordingly, by increasing the stress between the connection member COM2 and the third conductive layer 280, the connection member COM2 and the pad portion PD may be more closely coupled, and the restoration characteristics after being pressed by the connection member COM2 may be finely or suitably provided.

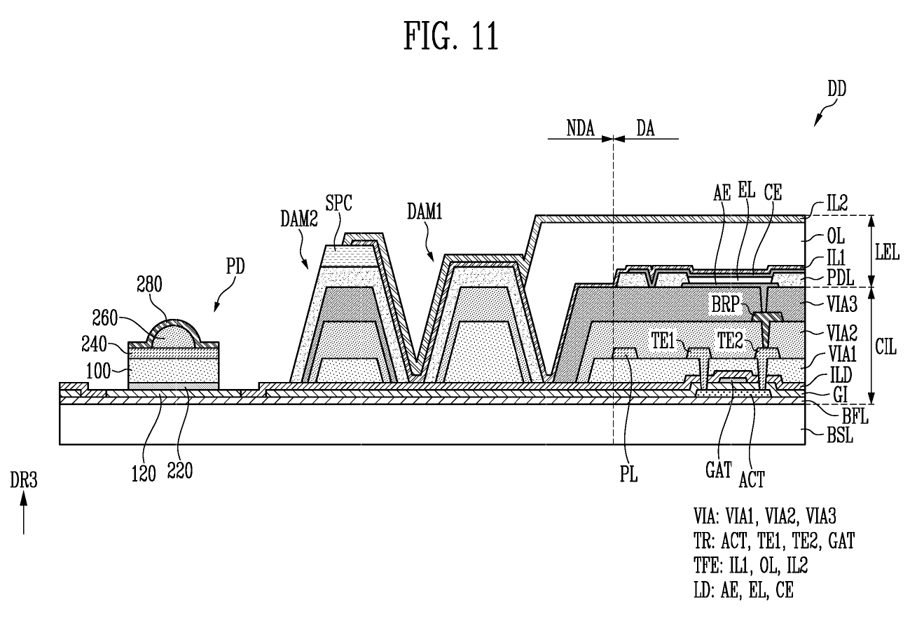

Referring to FIG. 11, the first conductive layer 220, the second conductive layer 240, the third conductive layer 280, and the intermediate cushion layer 260 may be disposed or provided inside an area in which the additional lower cushion layer 120 is disposed or provided in plan view.

For example, the additional lower cushion layer 120 may be patterned to extend over a relatively large area. The additional lower cushion layer 120 may be further expanded relative to the edges of the first conductive layer 220, the second conductive layer 240, the third conductive layer 280, and the intermediate cushion layer 260.

According to the present disclosure, the further lower cushion layer 120 may more closely induce a restoration by the depression of the connection member COM2.

The display device DD according to one or more embodiments may be applied to one or more suitable electronic devices 10. The electronic device 10 according to one or more embodiments may include the display device DD as described in one or more embodiments and may further include a module or device having an additional function other than the display device DD.

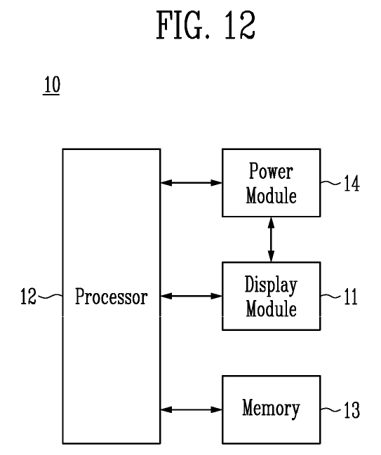

FIG. 12 is a block diagram of an electronic device according to one or more embodiments. Referring to FIG. 12, an electronic device 10 according to one or more embodiments may include a display module 11, a processor 12, a memory 13, and a power module 14.

The processor 12 may include at least one selected from among a central processing unit (CPU), an application processor (AP), a graphics processing unit (GPU), a communication processor (CP), an image signal processor (ISP), and a controller.

The memory 13 may store data information desired for the operation of the processor 12 or the display module 11. If (e.g., when) the processor 12 executes the application stored in the memory 13, the image data signal and/or the input control signal may be transmitted to the display module 11, and the display module 11 may process the received signal and output the image information through the display screen.

The power module 14 may include a power supply module, such as a power adapter and/or a battery device, and a power conversion module that converts power supplied by the power supply module to generate power desired for the operation of the electronic device 10. The power module 14 may be configured or provided to supply power to the display module 11.

At least one selected from among the components of the electronic device 10 as described in one or more embodiments may be included in the display device DD according to one or more embodiments. In one or more embodiments, one or more of the individual modules that are functionally included in one module may be included in the display device DD, and other parts may be provided separately from the display device DD. For example, the display device DD may include the display module 11, and the processor 12, the memory 13, and the power module 14 may be provided in the form of other devices in the electronic device 10 other than the display device DD.

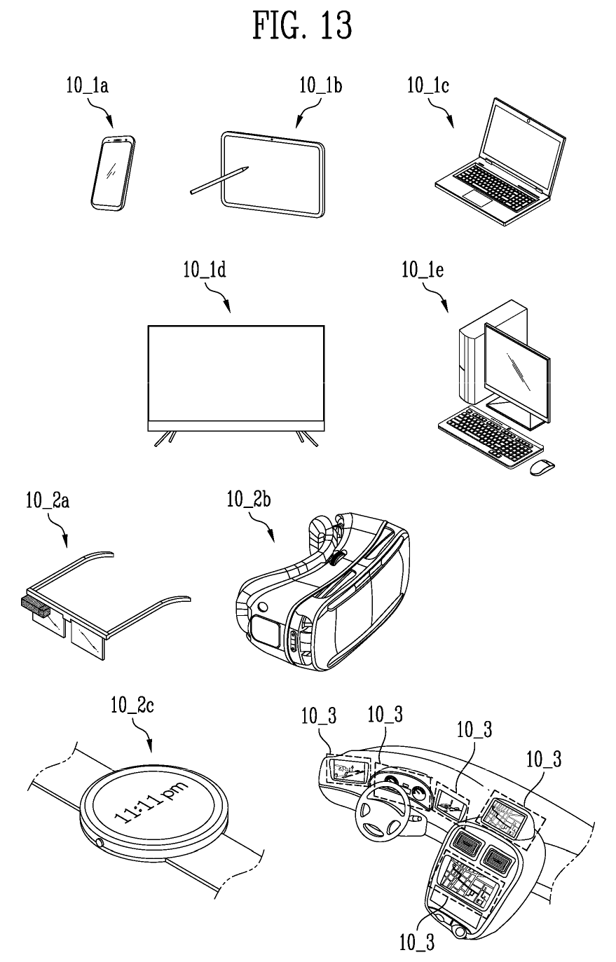

FIG. 13 is a schematic diagram of an electronic device according to one or more embodiments.

Referring to FIG. 13, one or more suitable electronic devices 10 to which a display device DD is applied according to one or more embodiments may include not only electronic devices for image display, such as a smartphone 10_1a, a tablet PC 10_1b, a laptop 10_1c, a TV 10_1d, and a desk monitor 10_1e, but also wearable electronic devices including a display module, such as smart glasses 10_2a, a head mounted display 10_2b, a smart watch 10_2c, and/or the like, an electronic device 10_3 for a vehicle including a display module, such as a center information display (CID), a room mirror display, and/or the like disposed or provided on an instrument panel, a center fascia, and a dashboard of a vehicle, and/or the like.

Although one or more embodiments of the present disclosure have been described with reference to the accompanying drawings, it should be understood that the present disclosure should not be limited to these embodiments but one or more suitable changes and modifications can be made within the spirit and scope of the appended claims and equivalents thereof, the detailed description of the present disclosure, and the accompanying drawings.

Therefore, the scope of the present disclosure should not be limited to one or more embodiments/examples, but should be determined by the appended claims as well as the equivalents thereof.

What is claimed is:

1. A display device comprising:
a display area and a non-display area provided in a periphery of the display area;
a base layer provided over the display area and the non-display area;
a pad portion on the base layer in the non-display area; and
a light-emitting element on the base layer in the display area,
wherein the pad portion comprises conductive layers electrically connected to each other, an intermediate cushion layer between the conductive layers, and an upper connection layer electrically connected to the conductive layers and provided on top of the pad portion,
wherein the light-emitting element comprises a first electrode, a second electrode, and a light-emitting layer electrically connected between the first electrode and the second electrode, and
wherein the upper connection layer and the first electrode comprise a same or substantially the same conductive material.

2. The display device as claimed in claim 1, wherein the upper connection layer comprises a first upper connection layer, a second upper connection layer on the first upper connection layer, and a third upper connection layer on the second upper connection layer,
wherein the first electrode comprises a (1-1)th electrode, a (1-2)th electrode on the (1-1)th electrode, and a (1-3)th electrode on the (1-2)th electrode,
wherein the first upper connection layer and the (1-1)th electrode comprise a same or substantially the same transparent conductive material,
wherein the second upper connection layer and the (1-2)th electrode comprise a same or substantially the same reflective conductive material, and
wherein the third upper connection layer and the (1-3)th electrode comprise a same or substantially the same transparent conductive material.

3. The display device as claimed in claim 2, wherein the first upper connection layer and the third upper connection layer comprise indium tin oxide (ITO), and
wherein the second upper connection layer comprises one or more selected from among gold (Au), silver (Ag), aluminum (Al), copper (Cu), and nickel (Ni).

4. The display device as claimed in claim 2, wherein the (1-3)th electrode has a first thickness, and
wherein the third upper connection layer has a second thickness that is less than the first thickness.

5. The display device as claimed in claim 4, wherein the first upper connection layer has a thickness of 10 Å to 300 Å,
wherein the second upper connection layer has a thickness of 500 Å to 10000 Å, and
wherein the third upper connection layer has a thickness of 10 Å to 300 Å.

6. The display device as claimed in claim 2, further comprising:
a gate conductive layer on the base layer in the display area;
an active layer on the base layer in the display area;
a first transistor electrode and a second transistor electrode that are electrically connected to the active layer; and
a via layer covering the first transistor electrode and the second transistor electrode,
wherein the conductive layers comprise a first conductive layer on the base layer, a second conductive layer on the first conductive layer, and a third conductive layer covering the intermediate cushion layer and electrically connected to the second conductive layer,
wherein the first conductive layer comprises a same or substantially the same conductive material as the gate conductive layer,
wherein the second conductive layer comprises a same or substantially the same conductive material as the first transistor electrode and the second transistor electrode, and
wherein the intermediate cushion layer comprises a same or substantially the same organic material as the via layer.

7. The display device as claimed in claim 6, wherein the upper connection layer entirely covers an upper surface of the third conductive layer and at least a portion of a side end portion of the third conductive layer.

8. The display device as claimed in claim 1, wherein the upper connection layer comprises a first upper connection layer, a second upper connection layer on the first upper connection layer, and a third upper connection layer on the second upper connection layer,
wherein the first electrode comprises a (1-1)th electrode, a (1-2)th electrode on the (1-1)th electrode, and a (1-3)th electrode on the (1-2)th electrode,
wherein the first upper connection layer and the (1-1)th electrode comprise a same or substantially the same reflective conductive material,
wherein the second upper connection layer and the (1-2)th electrode comprise a same or substantially the same reflective conductive material, and
wherein the third upper connection layer and the (1-3)th electrode comprise a same or substantially the same reflective conductive material.

9. The display device as claimed in claim 8, further comprising:
a connection portion comprising a drive integrated circuit (a drive IC) and a connection member patterned on the drive IC; and
a drive circuit portion electrically connected to the connection portion,
wherein the pad portion is electrically connected to the connection member through the upper connection layer.

10. The display device as claimed in claim 9, wherein the connection member comprises a conductive bump or a lead structure,
wherein the conductive layers comprise a first conductive layer on the base layer, a second conductive layer on the first conductive layer, and a third conductive layer covering the intermediate cushion layer and electrically connected to the second conductive layer, and
wherein the upper connection layer is on the third conductive layer, and the connection member and the third conductive layer are spaced apart from each other.

11. The display device as claimed in claim 10, wherein the third upper connection layer comprises an opening exposing a portion of the second upper connection layer, and
wherein the connection member is in contact with the second upper connection layer through the opening.

12. The display device as claimed in claim 10, wherein the third conductive layer comprises a (3-1)th conductive layer, a (3-2)th conductive layer on the (3-1)th conductive layer, and a (3-3)th conductive layer on the (3-2)th conductive layer,
wherein the (3-1)th conductive layer and the (3-3)th conductive layer comprise titanium (Ti),
wherein the (3-2)th conductive layer comprises aluminum (Al), and
wherein a top surface of the (3-2)th conductive layer is not exposed by the (3-3)th conductive layer.

13. The display device as claimed in claim 1, wherein the intermediate cushion layer comprises an organic material having a smaller modulus than the conductive layers, and
wherein the intermediate cushion layer has a cross-sectional shape having a curvature.

14. A display device comprising:
a display area and a non-display area provided in a periphery of the display area;
a base layer provided over the display area and the non-display area;
a pad portion on the base layer in the non-display area; and
a light-emitting element on the base layer in the display area,
wherein the pad portion comprises conductive layers electrically connected to each other, an intermediate cushion layer between the conductive layers, and a lower cushion layer between the base layer and the intermediate cushion layer, and
wherein at least one selected from among the conductive layers is between the intermediate cushion layer and the lower cushion layer.

15. The display device as claimed in claim 14, further comprising:
a gate conductive layer on the base layer in the display area;
an active layer on the base layer in the display area;
a first transistor electrode and a second transistor electrode that are electrically connected to the active layer;
a first via layer covering the gate conductive layer; and
a second via layer on the first via layer and covering the first transistor electrode and the second transistor electrode,
wherein the conductive layers comprise a first conductive layer on the base layer, a second conductive layer on the first conductive layer, and a third conductive layer covering the intermediate cushion layer and electrically connected to the second conductive layer,
wherein the first conductive layer comprises a same or substantially the same conductive material as the gate conductive layer,
wherein the second conductive layer comprises a same or substantially the same conductive material as the first transistor electrode and the second transistor electrode,
wherein the lower cushion layer comprises a same or substantially the same organic material as the first via layer, and
wherein the intermediate cushion layer comprises a same or substantially the same organic material as the second via layer.

16. The display device as claimed in claim 15, wherein the conductive layers and the intermediate cushion layer are in a region where the lower cushion layer is provided.

17. The display device as claimed in claim 15, further comprising:
a gate insulating layer, at least a portion of the gate insulating layer being between the gate conductive layer and the active layer; and an additional lower cushion layer comprising a same or substantially the same material as the gate insulating layer and provided between the first conductive layer and the base layer.

18. The display device as claimed in claim 17, wherein the first conductive layer, the second conductive layer, the third conductive layer, and the intermediate cushion layer are in a region where the additional lower cushion layer is provided.

19. An electronic device comprising:
a processor to provide input control signal;
a display device to output image information; and
a power module to supply power to the display device,
wherein the display device comprises:
a display area and a non-display area in a periphery of the display area;
a base layer over the display area and the non-display area;
a pad portion on the base layer in the non-display area; and
a light-emitting element on the base layer in the display area,
wherein the pad portion comprises conductive layers electrically connected to each other, an intermediate cushion layer between the conductive layers, and an upper connection layer electrically connected to the conductive layers and provided on top of the pad portion,
wherein the light-emitting element comprises a first electrode, a second electrode, and a light-emitting layer electrically connected between the first electrode and the second electrode, and
wherein the upper connection layer and the first electrode comprise a same or substantially the same conductive material.

20. The electronic device as claimed in claim 19, wherein the electronic device is applied to a smartphone, a tablet PC, a laptop, a TV, a monitor for a desk, smart glasses, a head mounted display, a smart watch, a center information display (CID) on an instrument panel, a center fascia, or a dashboard of a vehicle, or a room mirror display.
